(19) United States
(12) Patent Application Publication
(10) Pub. No.: US 2009/0038667 A1
(43) Pub. Date: Feb. 12, 2009

(54) THERMOELECTRIC CONVERSION MODULE AND HEAT EXCHANGER AND THERMOELECTRIC POWER GENERATOR USING IT

(75) Inventors: Shinsuke Hirono, Kanagawa-ken (JP); Masami Okamura, Kanagawa-ken (JP); Fumiyuki Kawashima, Chiba-ken (JP)

Correspondence Address: FOLEY AND LARDNER LLP;SUITE 500, 3000 K STREET NW, WASHINGTON, DC, 20007, US

(73) Assignees: Kabushiki Kaisha Toshiba; Toshiba Materials Co., LTD.

(21) Appl. No.: 12/094,729

(22) PCT Filed: Nov. 22, 2006
(86) PCT No.: PCT/JP2006/323299

§ 371 Date: May 22, 2008

(30) Foreign Application Priority Data
Nov. 29, 2005 (JP) 2005-344045

(51) Int. Cl. H01L 35/30; H01L 35/00

(52) U.S. Cl. 136/205; 136/200

(57) ABSTRACT

A thermoelectric conversion module (10) used at temperatures of 300° C. or more includes a first substrate (15) disposed on a low temperature side, a second substrate (16) disposed on a high temperature side, first and second electrode members (13, 14) provided to face the element mounting regions of these substrates (15, 16), and a plurality of thermoelectric elements (11, 12) disposed between the electrode members (13, 14). An occupied area ratio of the thermoelectric elements (11, 12) in the module is set to 69% or more, and an output per unit area of the thermoelectric conversion module (10) is made to increase.

### TECHNICAL FIELD

The present invention relates to a thermoelectric conversion module used under high temperatures and a heat exchanger and a thermoelectric power generator using it.

### BACKGROUND ART

Since depletion of resources is supposed, it is very important to develop measures for effectively using energy, and various systems are proposed. Among them, the thermoelectric element is expected to provide a means for recovering the energy discarded uselessly as waste heat in the past. The thermoelectric element is used as a thermoelectric conversion module having p-type thermoelectric elements (p-type thermoelectric semiconductors) and n-type thermoelectric elements (n-type thermoelectric semiconductors) alternately connected in series.

The conventional thermoelectric conversion module is hardly put to practical use for generation of electricity because the output per unit area, namely an output density, is low. For improvement of the output density of the thermoelectric conversion module, it is necessary to improve the performance of the thermoelectric element and to increase the temperature difference of the module when it is used. In other words, it is important to realize a thermoelectric conversion module usable at a high temperature. Specifically, there are demands for a thermoelectric element usable in a high-temperature environment of 300° C. or higher. As the thermoelectric element usable in a high-temperature environment, for example, a thermoelectric material (hereinafter called a half-Heusler material) which has an intermetallic compound having an MgAgAs type crystal structure as a main phase is known (see References 1, 2). The half-Heusler material exhibits a semiconducting property and is being watched with interest as a novel thermoelectric conversion material. It is reported that an intermetallic compound having an MgAgAs crystal structure partially exhibits a high Seebeck effect under room temperature. In addition, the half-Heusler material has a high usable temperature and is expected to improve the thermoelectric conversion efficiency, so that it is an attractive material for the thermoelectric conversion module of a power generator using a high temperature heat source.

But, when the conventional thermoelectric conversion module is used in a high temperature environment, an electromotive force which is originally possessed by the thermoelectric element is not utilized fully. Therefore, the electromotive force obtained is smaller than the electromotive force which is assumed from the module structures of plural thermoelectric elements. In other words, the conventional thermoelectric conversion module has a problem of suffering from lowering of the electromotive force.

Reference 1: JP-A 2004-356607 (KOKAI)

Reference 2: JP-A 2005-116746 (KOKAI)

### SUMMARY OF THE INVENTION

According to an aspect of the present invention, there are provided a thermoelectric conversion module whose practical use is improved by improving an electromotive force when a module structure is formed, and a heat exchanger and a thermoelectric power generator using the thermoelectric conversion module.

A thermoelectric conversion module according to an aspect of the present invention includes: a first substrate, disposed on a low-temperature side, having an element mounting region; a second substrate, disposed on a high-temperature side, having an element mounting region; first electrode members provided to the element mounting region of the first substrate; second electrode members provided to the element mounting region of the second substrate so as to oppose the first electrode members; and a plurality of thermoelectric elements disposed between the first electrode members and the second electrode members, the thermoelectric elements electrically connecting to both of the first and second electrode members, wherein the thermoelectric conversion module is used at a temperature of 300° C. or more, wherein an occupied area ratio of the thermoelectric elements in the element mounting region is 69% or more, where an area of the element mounting region of the substrate is area A, a total cross-sectional area of the thermoelectric elements is area B, and the occupied area ratio of the thermoelectric elements is (area B/area A)×100(%).

A heat exchanger according to another aspect of the present invention includes: a heating side, a cooling side, and the thermoelectric conversion module according to the aspect of the invention disposed between the heating side and the cooling side. A thermoelectric power generator according to another aspect of the present invention includes: the heat exchanger according to the aspect of the invention; and a heat supply unit for supplying heat to the heat exchanger, wherein the heat supplied by the heat supply unit is converted to electric power by the thermoelectric conversion module of the heat exchanger to generate electricity.

### BRIEF DESCRIPTION OF THE DRAWINGS

FIG. 1 is a sectional view showing a structure of a thermoelectric conversion module according to an embodiment of the present invention.

FIG. 2 is a diagram showing a planar state of the thermoelectric conversion module shown in FIG. 1.

FIG. 3 is a sectional view showing a state that insulating members are provided as fixing jigs on the thermoelectric conversion module shown in FIG. 1.

FIG. 4 is a diagram showing a planar state of the thermoelectric conversion module shown in FIG. 3.

FIG. 5 is a sectional view showing a supporting base for the insulating member shown in FIG. 4.

FIG. 6 is a diagram showing a crystal structure of an MgAgAs type intermetallic compound.

FIG. 7 is a sectional view showing a modified example of the thermoelectric conversion module shown in FIG. 1.

FIG. 8 is a perspective view showing a structure of a heat exchanger according to an embodiment of the present invention.

FIG. 9 is a diagram showing a structure of a thermoelectric power generator according to an embodiment of the present invention.

### EXPLANATION OF REFERENCE NUMERALS

11 . . . p-type thermoelectric element, 12 . . . n-type thermoelectric element, 13 . . . first electrode member, 14 . . . second electrode member, 15 . . . first substrate, 16 . . . second substrate, 17, 18, 25 . . . bonded portion, 19, 20 . . . insulating member (fixing jig), 23, 24 . . . backing metal plate, 30 . . . heat exchanger, 40 . . . exhaust heat utilizing power system.

### MODE FOR CARRYING OUT THE INVENTION

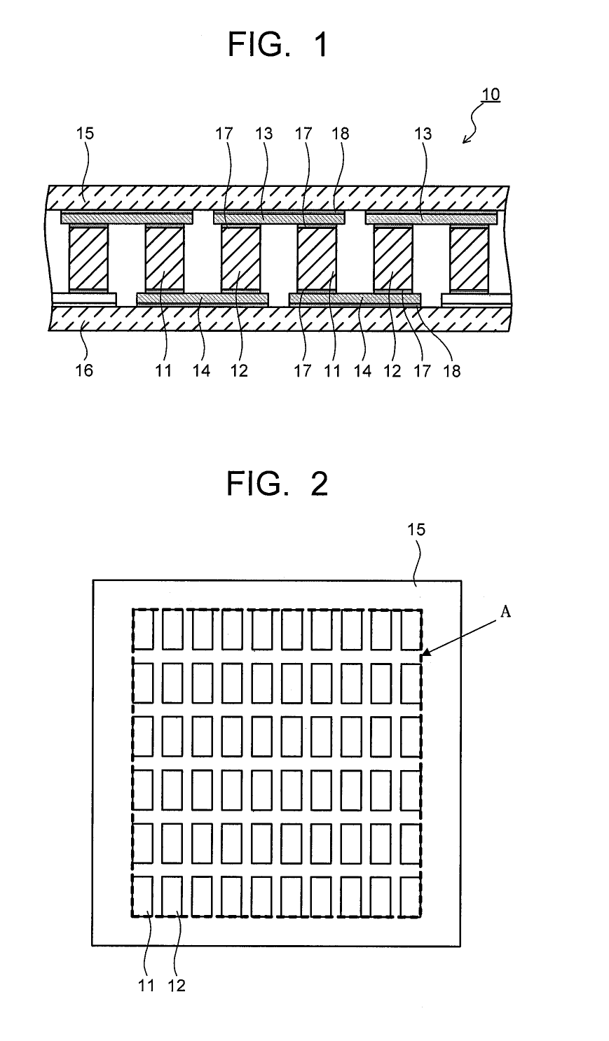

An embodiment of the invention will be described below with reference to the drawings. FIG. 1 is a sectional view showing a structure of the thermoelectric conversion module according to the embodiment of the present invention. A thermoelectric conversion module 10 shown in FIG. 1 is used at a temperature of 300° C. or higher and has plural p-type thermoelectric elements 11 and plural n-type thermoelectric elements 12. The p-type thermoelectric elements 11 and the n-type thermoelectric elements 12 are alternately arranged on the same plane and in a matrix pattern as an entire module to configure a thermoelectric element group.

The p-type thermoelectric element 11 and the n-type thermoelectric element 12 are arranged adjacent to each other. A first electrode member 13 is arranged on the tops of one p-type thermoelectric element 11 and its adjacent one n-type thermoelectric element 12 to mutually connect them. Meanwhile, a second electrode member 14 is arranged on the bottoms of one p-type thermoelectric element 11 and its adjacent one n-type thermoelectric element 12 to mutually connect them. The second electrode member 14 is arranged to face the first electrode member 13. The first electrode member 13 and the second electrode member 14 are arranged in a state that they are displaced from each other by one element.

Thus, the plural p-type thermoelectric elements 11 and the plural n-type thermoelectric elements 12 are electrically connected in series. Specifically, the plural first electrode members 13 and the plural second electrode members 14 are arranged so that DC current is sequentially flown to the p-type thermoelectric element 11, the n-type thermoelectric element 12, the p-type thermoelectric element 11, the n-type thermoelectric element 12, . . . . It is to be noted that the first electrode member 13 and the second electrode member 14 are not required to be mutually opposed completely but the first and second electrode members 13, 14 may be opposed partly.

The first and second electrode members 13, 14 are preferably composed of a metal material having as a main component at least one selected from Cu, Ag and Fe. Since such metal materials are soft, they serve to ease a thermal stress when used to bond to the thermoelectric elements 11, 12. Therefore, it becomes possible to enhance the reliability in terms of a thermal stress, e.g., a heat cycle property, of the bonded portion between the first and second electrode members 13, 14 and the thermoelectric elements 11, 12. Besides, since the metal material having Cu, Ag and Fe as a main component excels in electrical conductivity, electric power generated by, for example, the thermoelectric conversion module 10 can be taken out efficiently.

A first substrate 15 is disposed outside (surface opposite to the surface bonded to the thermoelectric elements 11, 12) the first electrode member 13. The first electrode member 13 is bonded to the element mounting region of the first substrate 15. A second substrate 16 is disposed outside the second electrode member 14. The second electrode member 14 is bonded to the element mounting region of the second substrate 16. The element mounting region of the second substrate 16 has the same shape as that of the first substrate 15. The first and second electrode members 13, 14 are supported by the first and second substrates 15, 16 to maintain the module structure.

An insulating substrate is used for the first and second substrates 15, 16. The first and second substrates 15, 16 are preferably composed of an insulating ceramics substrate. For the substrates 15, 16, it is desirable to use a ceramics substrate which is composed of a sintered body having as a main component at least one type selected from aluminum nitride, silicon nitride, alumina, magnesia and silicon carbide excelling in thermal conductance. For example, it is desirable to use a high thermal conductance silicon nitride substrate (silicon nitride sintered body) having a coefficient of thermal conductivity of 65 W/m·K or more and a three-point bending strength of 600 MPa or more as described in JP-A 2002-203993 (KOKAI).

The p-type and n-type thermoelectric elements 11, 12 are bonded to the first and second electrode members 13, 14 via bonded portions 17 with a brazing material. The first and second electrode members 13, 14 and the p-type and n-type thermoelectric elements 11, 12 are connected electrically and mechanically via the bonded portions (brazing material layers) 17. Similarly, the first and second electrode members 13, 14 are bonded to the first and second substrates 15, 16 via bonded portions 18.

In the thermoelectric conversion module 10, the plural thermoelectric elements 11, 12 are arranged in a matrix pattern. When it is assumed that the element mounting region of the substrates 15, 16 has area A, the total cross-sectional area of the plural thermoelectric elements 11, 12 has area B, and the occupied area ratio of the thermoelectric elements 11, 12 in the element mounting region is (area B/area A)×100(%), the thermoelectric elements 11, 12 are disposed to have the occupied area ratio of 69% or more. The area A of the element mounting region indicates an area which is surrounded by the thermoelectric elements 11, 12 of the outermost peripheral portion among the plural thermoelectric elements 11, 12 which are disposed on the substrate 15, 16 as shown in FIG. 2. FIG. 2 shows the first substrate 15 only, but the second substrate 16 also has an element mounting region having the same area. The electrode members 13, 14 are omitted from FIG. 2.

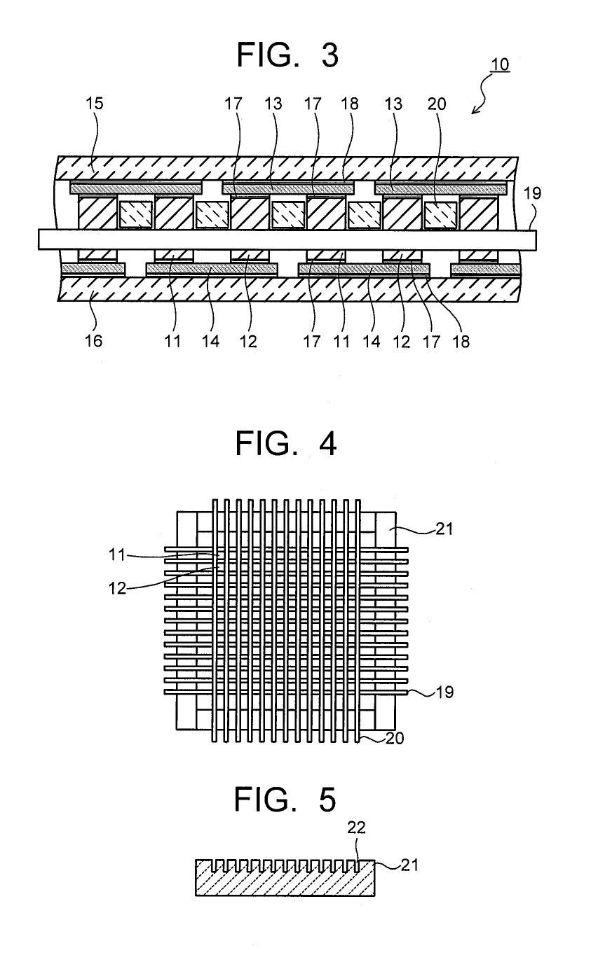

A ratio of the area B to the area A indicates an occupied area (mounting density) of the thermoelectric elements 11, 12. In other words, a ratio of nonmounted portions of the thermoelectric elements 11, 12 (a ratio of the space between the thermoelectric elements 11, 12) is found from the B/A ratio. It is presumed that a lowering factor of an electromotive force of a conventional thermoelectric conversion module is a mounting density (packing density) of the thermoelectric elements. When the thermoelectric elements are arranged as shown in FIG. 3 through FIG. 5 of Patent Literature 1 described above, the occupied area ratio of the thermoelectric elements becomes about 50 to 60%. In other words, the unoccupied portion of the thermoelectric elements becomes about 50 to 40%. It is presumed that the heat loss from the element unoccupied portion is a main lowering factor of the electromotive force.

Specifically, if the total sum of element cross-sectional areas occupying the thermoelectric conversion module is small, heat quantity applied to a high-temperature side substrate is radiated as heat from the element unoccupied portion of the high-temperature side substrate and the electrode members positioned at that portion toward the low-temperature side substrate, and a heat loss is increased. Therefore, the temperature difference (temperature difference between top and bottom ends) between a high-temperature side end portion and a low-temperature side end portion of the thermoelectric element cannot be increased to a sufficient value with respect to the heat quantity applied to the thermoelectric conversion module. Thus, the heat loss due to radiation based on the element unoccupied portion is considered to be a lowering factor of electromotive force of a conventional thermoelectric conversion module.

When the same number of elements is used for comparison, the total sum of the element cross-sectional area occupying the thermoelectric conversion module 10 is increased, and the internal resistance of the module 10 becomes small. In addition, the thermoelectric conversion module 10 used in a high temperature environment has the heat loss, due to the element unoccupied portion, of the heat quantity applied to the high-temperature side substrate decreased, so that a temperature difference between the top and bottom ends of the thermoelectric elements 11, 12 becomes large. Thus, since the electromotive forces of the thermoelectric elements 11, 12 increase, the output of the thermoelectric conversion module 10 can be improved.

According to the thermoelectric conversion module 10 in which the thermoelectric elements 11, 12 have an occupied area ratio of 69% or more, the reducing effect of the heat loss due to the radiation from the element unoccupied portion can be caused to act effectively at a practical level in addition to the internal resistance decreasing effect, so that the electromotive force of the thermoelectric elements 11, 12 is increased. Thus, the thermoelectric conversion module 10 with the output improved can be realized. It is desirable that the occupied area ratio of the thermoelectric elements 11, 12 in the thermoelectric conversion module 10 is 73% or more, enabling to enhance the module output further more. But, if the occupied area ratio is excessively high, a short circuit occurs easily between the adjacent thermoelectric elements 11, 12, so that it is desirable that the occupied area ratio of the thermoelectric elements 11, 12 is 90% or less.

It is desirable that the element mounting region of the substrates 15, 16 has the area A of 100 mm² or more and 10000 mm² or less. In a case where the thermoelectric conversion module 10 is used under a high temperature environment of 300° C. or more, the element mounting region of the substrates 15, 16 has the area A of exceeding 10000 mm², and reliability to a thermal stress decreases. Meanwhile, if the element mounting region has the area A of less than 100 mm², an effect of having the plural thermoelectric elements 11, 12 as a module cannot be obtained satisfactorily. It is desirable that the area A is in a range of 400 to 3600 mm².

The cross-sectional area of each of the thermoelectric elements 11, 12 is preferably 1.9 mm² or more and 100 mm² or less. In a case where the thermoelectric conversion module 10 is used in a high temperature environment of 300° C. or more, if the cross-sectional area of each of the thermoelectric elements 11, 12 exceeds 100 mm², reliability to a thermal stress decreases. Meanwhile, if the cross-sectional area of each of the thermoelectric elements 11, 12 is less than 1.9 mm², it is hard to enhance the occupied area ratio of the thermoelectric elements 11, 12. In other words, the space between the thermoelectric elements 11, 12 is hardly set to 0.3 mm or less because of their arrangement precision, dimensional precision and the like. Therefore, to set the occupied area ratio of the thermoelectric elements 11, 12 to 69% or more, it is desirable that the cross-sectional area of each of the thermoelectric elements 11, 12 is 1.9 mm² or more. It is more desirable that the cross-sectional area of each of the thermoelectric elements 11, 12 is in a range of 2.5 to 25 mm².

Management of the occupied area ratio of the thermoelectric elements 11, 12 is effective for the thermoelectric conversion module 10 using a large number of thermoelectric elements 11, 12. Specifically, it is effective for the thermoelectric conversion module 10 having 16 or more, and 50 or more thermoelectric elements 11, 12. The more the number of thermoelectric elements 11, 12 increases, the greater the effect of improving the occupied area ratio becomes. As a result, it becomes possible to obtain the thermoelectric conversion module 10 having high output. Specifically, the thermoelectric conversion module 10 having module output (output density) to the area A of the element mounting region of the substrates 15, 16 of 1.3 W/cm² or more can be realized.

To set the occupied area ratio of the thermoelectric elements 11, 12 to 69% or more, it is desirable that the space (interelement spacing) between the adjacent thermoelectric elements 11, 12 is 0.7 mm or less, though variable depending on the area of the element mounting region of the substrates 15, 16 and the cross-sectional area of each of the thermoelectric elements 11, 12. But, even if the element spacing is merely set to be 0.7 mm or less, there is a high possibility of causing a short circuit between the adjacent thermoelectric elements 11, 12 because the brazing material of the bonded portion 17 gets wet and spreads at the time when the thermoelectric elements 11, 12 and the first and second electrode members 13, 14 are bonded.

In such a case, it is effective to use a brazing material containing carbon. By containing carbon in the brazing material, wetting and spreading are suppressed, and a possibility of a short circuit occurring between the thermoelectric elements 11, 12 is decreased. Therefore, the occupied area ratio of the thermoelectric elements 11, 12 can be improved. It is desirable that the interelement spacing is determined to be 0.7 mm or less as described above. But, if the interelement spacing is excessively decreased, a short circuit occurs easily. Considering the arrangement precision, dimensional precision and the like of the thermoelectric elements 11, 12, it is desirable to set the interelement spacing to 0.3 mm or more.

It is desirable to use an active metal brazing material containing carbon for the bonded portion 17 between the thermoelectric elements 11, 12 and the electrode members 13, 14. As the active metal brazing material, there is used a brazing material composed of a main material composed of at least one selected from Ag, Cu and Ni which is mixed with at least one of active metal selected from Ti, Zr, Hf, Ta, V and Nb in a range of 1 to 10 mass %. If the content of the active metal is excessively small, there is a possibility of degrading a bonding property with respect to the thermoelectric elements 11, 12. If the content of the active metal is excessively large, its properties as the brazing material are degraded. The active metal brazing material is also effective for not only the bonding between the thermoelectric elements 11, 12 and the electrode members 13, 14 but also the bonding between the electrode members 13, 14 and the substrates 15, 16.

A brazing material component (main material) which combines an active metal is composed of at least one type selected from Ag, Cu and Ni. For the main material of the active metal brazing material, it is desirable to use an Ag—Cu alloy (Ag—Cu brazing material) containing Ag in a range of 60 to 75 mass %. The Ag—Cu alloy is desired to further have a eutectic composition. The active metal brazing material may contain at least one type selected from Sn and In in a range of 8 to 18 mass %. It is desirable that the active metal brazing material contains at least one type of active metal selected from Ti, Zr and Hf in a range of 1 to 8 mass %, and the balance is composed of an Ag—Cu alloy (Ag—Cu brazing material).

It is desirable to bond the thermoelectric elements 11, 12 and the electrode members 13, 14 by using a brazing material which has carbon in a range of 0.5 to 3 mass % contained in the above-described active metal brazing material. If a carbon blending amount to the active metal brazing material is less than 0.5 mass %, there is a possibility that an effect of suppressing the wetting and spreading of the brazing material cannot be obtained satisfactorily. Meanwhile, if the carbon blending amount exceeds 3 mass %, a high bonding temperature is required, and there is a possibility that the strength of the brazing material layer itself is decreased.

The thermoelectric elements 11, 12 and the electrode members 13, 14 are bonded by using an active metal brazing material containing carbon and heating at a temperature of, for example, about 760 to 930° C. By bonding the thermoelectric elements 11, 12 and the electrode members 13, 14 under such a high temperature, excellent bonding strength can be maintained at a temperature in a range of about 300° C. or more and 700° C. or less. Therefore, the thermoelectric conversion module 10 which is used under a high temperature of 300° C. or more can be provided with a suitable structure. The active metal brazing material contributes to the improvement of the bonding strength between the thermoelectric elements 11, 12 and the electrode members 13, 14 which are composed of the thermoelectric material which has as the main phase the intermetallic compound having an MgAgAs crystal structure described later.

In addition, to enhance the occupied area ratio by decreasing the space between the thermoelectric elements 11, 12, it is effective to dispose the insulating member between the adjacent thermoelectric elements 11, 12. It is effective to use a jig for fixing the thermoelectric elements 11, 12 to prevent a short circuit from occurring between the thermoelectric elements 11, 12 and to accurately dispose the thermoelectric elements 11, 12 at prescribed positions on the substrates 15, 16. In a case where a metallic fixing jig is used, it is necessary to remove the fixing jig before bonding at a high temperature in order to prevent breakage of the elements due to a thermal expansion coefficient difference between the elements and the jig and seizing of the jig to the elements. But, if the jig is removed in an unbonded state, the elements tend to be displaced or inclined, and if the interelement spacing is small, there is a high possibility of a short circuit between the elements because of the displacement or inclination of the elements.

Accordingly, the elements can be prevented from displacing or inclining at the time of bonding by disposing a fixing jig which is not required to be removed when bonding at a high temperature and is composed of an insulating member, between the thermoelectric elements 11, 12. As shown in FIG. 3 through FIG. 5, rod-shape insulating members 19, 20 are prepared as the fixing jig. The insulating members 19 in a transverse direction and the insulating members 20 in a longitudinal direction are disposed in a grid pattern between the thermoelectric elements 11, 12 disposed in a matrix pattern. The positions of the insulating members 19, 20 are specified by a supporting base 21 which is disposed outside the thermoelectric elements 11, 12. The supporting base 21 has slits 22 for receiving the insulating members 19, 20. The interelement spacing can be made narrow by preventing the displacement and inclination of the thermoelectric elements 11, 12 by the insulating members 19, 20.

The insulating members 19, 20 are preferably formed of a material having a low thermal expansion coefficient or a material having a thermal expansion coefficient similar to those of the thermoelectric elements 11, 12. For the insulating members 19, 20, for example, an alumina sintered body, a silicon nitride sintered body, a magnesia sintered body or the like is used. In addition, a resin having high airtightness, glass material or the like may be used. Such insulating material can be used, as it is, as the oxidation-resistant sealing material, so that the sealing step of the thermoelectric conversion module 10 can be omitted. Thus, the insulating members 19, 20 are disposed as a fixing jig between the adjacent thermoelectric elements 11, 12, and the thermoelectric conversion module 10 which has an occupied area ratio of the thermoelectric elements 11, 12 enhanced without causing a short circuit between the elements can be realized.

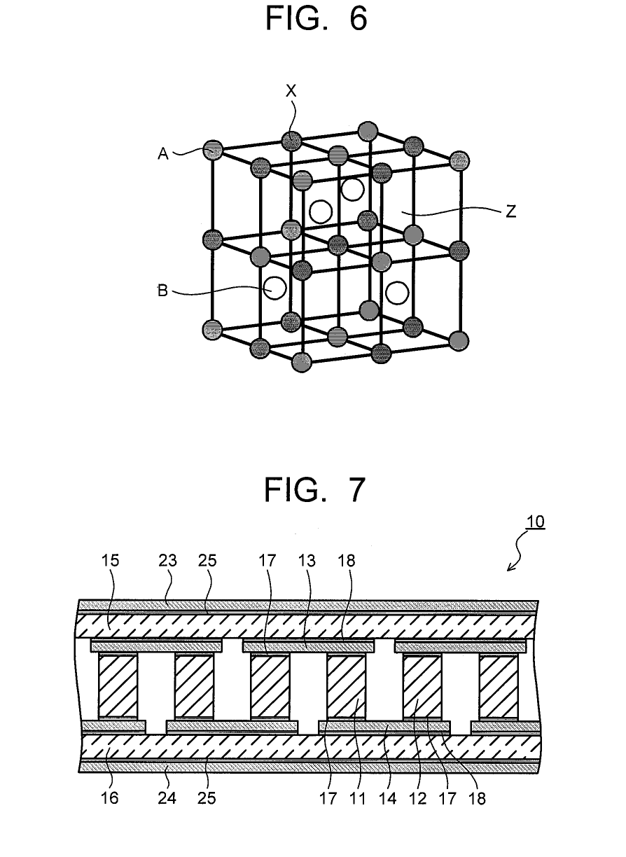

The p-type thermoelectric element 11 and the n-type thermoelectric element 12 are preferably composed of thermoelectric material (half-Heusler material) which has an intermetallic compound having an MgAgAs crystal structure as a main phase. The main phase indicates a phase having the highest volume fraction among the configured phases. The half-Heusler material is being watched with interest as a thermoelectric conversion material, and its high thermoelectric performance has been reported. The half-Heusler compound is an intermetallic compound which is represented by a chemical formula ABX, and has a cubic MgAgAs crystal structure. The half-Heusler compound has a crystal structure having atoms B inserted into an NaCl crystal lattice based on atoms A and atoms X as shown in FIG. 6. And, Z represents a hole.

As a A-site element of the half-Heusler compound, it is general to use at least one type of element selected from III group elements (rare-earth element including Sc, Y, etc.), IV group elements (Ti, Zr, Hf, etc.), and V group elements (V, Nb, Ta, etc.). As a B-site element, there is used at least one type of element selected from VII group elements (Mn, Tc, Re, etc.), VIII group elements (Fe, Ru, Os, etc.), IX group elements (Co, Rh, Ir, etc.), and X group elements (Ni, Pd, Pt, etc.). As an X-site element, there is used at least one type of element selected from XIII group elements (B, Al, Ga, In, Tl), XIV group elements (C, Si, Ge, Sn, Pb, etc.), and XV group elements (N, P, As, Sb, Bi).

For the p-type and n-type thermoelectric elements 11, 12, it is desirable to apply a material which has a composition represented by:

general formula: AₓB_{y}X_{100-x-y} (1)

(where, A represents at least one of element selected from Ti, Zr, Hf and rare-earth elements, B represents at least one of element selected from Ni, Co and Fe, X represents at least one of elements selected from Sn and Sb, and x and y represent a numeral satisfying 30≦x≦35 atom %, 30≦y≦35 atom %), and which has an intermetallic compound (half-Heusler compound) having an MgAgAs crystal structure as a main phase.

In addition, the p-type and n-type thermoelectric elements 11, 12 are desirably composed of a material which has a composition represented by:

general formula: (TiₐZr_{b}Hf_{c})ₓB_{y}X_{100-x-y} (2)

(where, a, b, c, x and y represent a numeral satisfying 0≦a≦1, 0≦b≦1, 0≦c≦1, a+b+c=1, 30≦x≦35 atom %, 30≦y≦35 atom %), and which has an intermetallic compound (half-Heusler compound) having an MgAgAs crystal structure as a main phase.

The half-Heusler compounds represented by the formulae (1) and (2) exhibit a particularly high Seebeck effect and have a high usable temperature (specifically, 300° C. or more). Therefore, they are effective for the thermoelectric elements 11, 12 of the thermoelectric conversion module 10 which uses a high temperature heat source and generates electricity. In the formula (1) and the formula (2), amount (x) of the A-site element is preferably in a range of 30 to 35 atom % to obtain a high Seebeck effect. Similarly, amount (y) of the B-site element is also preferably in a range of 30 to 35 atom %.

As the rare-earth element configuring the A-site element, it is desirable to use Y, La, Ce, Pr, Nd, Sm, Gd, Tb, Dy, Ho, Er, Tm, Yb, Lu or the like. In the formula (1) and the formula (2), the A-site element may be partially substituted by V, Nb, Ta, Cr, Mo, W or the like. The B-site element may be partially substituted by Mn, Cu or the like. The X-site element may be partially substituted by Si, Mg, As, Bi, Ge, Pb, Ga, In or the like.

The thermoelectric conversion module 10 is composed of the above-described elements. In addition, the metal plates 23, 24 of the same material as the electrode members 13, 14 may be disposed outside the first and second substrates 15, 16 as shown in FIG. 7. The metal plates 23, 24 are bonded to the substrates 15, 16 via the bonded portion 25 which applies an active metal brazing material in the same manner as the bonding of the electrode members 13, 14 and the substrates 15, 16. The metal plates (electrode members 13, 14 and metal plates 23, 24) of the same material are bonded to either surface of the first and second substrates 15, 16 to suppress crack generation or the like due to a thermal expansion difference between the substrates 15, 16 and the electrode members 13, 14.

The thermoelectric conversion module 10 shown in FIG. 1 or FIG. 7 is used to dispose the first substrate 15 on a low-temperature side (L) and the second substrate 16 on a high-temperature side (H) so as to provide a temperature difference between the upper and lower substrates 15, 16. A potential difference is generated between the first electrode member 13 and the second electrode member 14 based on the temperature difference, and electric power can be taken out by connecting a load to the electrode terminal. The thermoelectric conversion module 10 is used effectively as the power generator. The thermoelectric elements 11, 12 composed of a half-Heusler material can be used under a temperature of 300° C. or more. In addition, since the internal resistance and heat resistance are decreased as the entire module in addition to the possession of the high thermoelectric conversion performance, a high-efficiency power generator using a high temperature heat source can be realized.

The thermoelectric conversion module 10 is not limited to the use of power generation to convert heat into electricity but also can be used for the heating usage to convert electricity to heat. In other words, when DC current is flown to the p-type thermoelectric element 11 and the n-type thermoelectric element 12 which are connected in series, heat is radiated at one substrate, and heat is absorbed at the other substrate. Therefore, a subject can be heated by disposing the subject on the substrate on the heat radiation side. For example, a semiconductor manufacturing apparatus controls a semiconductor wafer temperature, and the thermoelectric conversion module 10 can be applied to the temperature control.

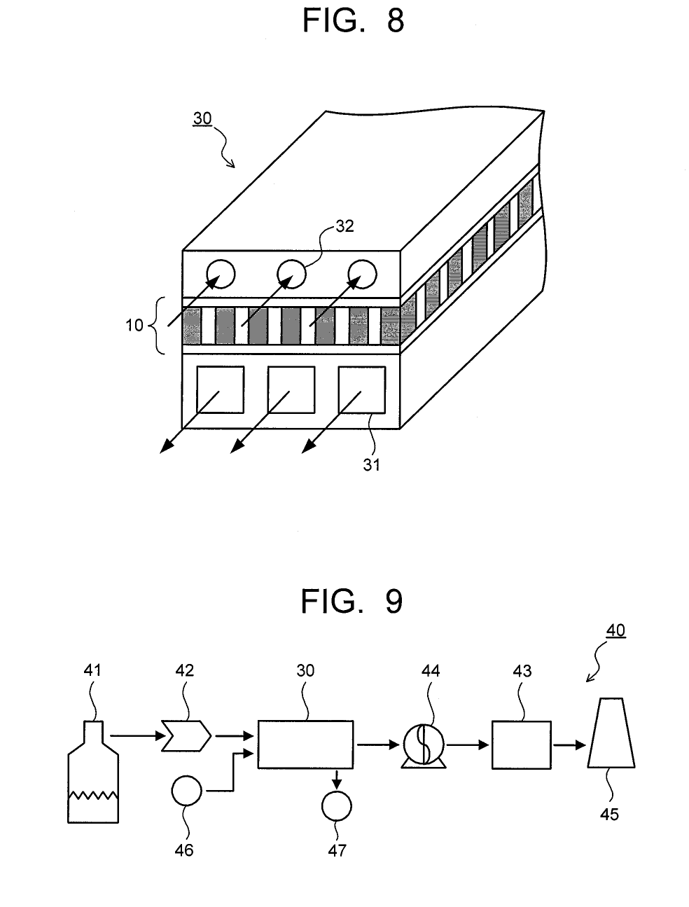

Then, an embodiment of the heat exchanger of the present invention is described below. The heat exchanger according to the embodiment of the present invention is provided with the thermoelectric conversion module 10 according to the above-described embodiment. The heat exchanger has a heating surface and a cooling surface and has a structure that the thermoelectric conversion module 10 is incorporated between them. FIG. 8 is a perspective view showing a structure of the heat exchanger according to the embodiment of the present invention. In a heat exchanger 30 shown in FIG. 8, gas passages 31 are disposed in one side surface of the thermoelectric conversion module 10 and water passages 32 are disposed in the opposite side surface.

For example, a high temperature exhaust gas from a waste incineration plant is introduced into the gas passages 31, while cooling water is introduced into the water passages 32. One side face of the thermoelectric conversion module 10 becomes a high-temperature side by the high temperature exhaust gas flowing through the gas passages 31, and the other becomes a low-temperature side by the cooling water flowing through the water passages 32. Electric power is taken out from the thermoelectric conversion module 10 based on the temperature difference. The cooling side (cooling surface) of the heat exchanger 3Q is not limited to water cooling but may also be air cooling. The heating side (heating surface) is not limited to the high temperature exhaust gas from a combustion furnace but may be, for example, exhaust gas of an internal combustion engine represented by an automobile engine, a boiler interior water pipe, or a combustion portion itself for combusting various types of fuels.

An embodiment of the thermoelectric power generator of the present invention is described below. The thermoelectric power generator according to the embodiment of the present invention is provided with the heat exchanger 30 of the above-described embodiment. The thermoelectric power generator has a means for supplying heat for power generation to the heat exchanger 30, and the heat supplied by the heat supply means is converted into electricity by the thermoelectric conversion module 10 of the heat exchanger 30 to generate electricity.

FIG. 9 shows a structure of an exhaust heat utilizing power generating system applying the thermoelectric power generator according to an embodiment of the present invention. An exhaust heat utilizing power generating system 40 shown in FIG. 9 has a structure that the heat exchanger 30 according to the embodiment is added to a waste incineration system which comprises an incinerator 41 for burning combustible waste, an air blowing fan 44 for blowing air to exhaust smoke treatment equipment 43 by absorbing an exhaust gas 42 and a chimney 45 for diffusing the exhaust gas 42 into the atmosphere. When the waste is burnt by the incinerator 41, the high temperature exhaust gas 42 is produced. The exhaust gas 42 is introduced into the heat exchanger 30 and cooling water 46 is also introduced at the same time, a temperature difference is generated at both ends of the thermoelectric conversion module 10 in the heat exchanger 30, and electric power is taken out. The cooling water 46 is discharged as hot water 47.

The thermoelectric power generator applying the heat exchanger according to the embodiment can be applied to not only the waste incineration system, but also to facilities having various types of incinerators, heating furnaces, melting furnaces and the like. It is also possible to use an exhaust pipe of an internal combustion engine as the gas passage for the high temperature exhaust gas, and a boiler interior water pipe of a steam thermal power generating plant can also be used as a heat supplying means. For example, the heat exchanger of the embodiment can be arranged on the surface of the boiler interior water pipe or the fins of the water pipe of the steam thermal power generating plant to determine a high-temperature side on the side of the boiler interior and a low-temperature side on the side of the water pipe, so that electric power and steam supplied to the steam turbine can be obtained at the same time, and the efficiency of the steam thermal power generating plant can be improved. In addition, a means for supplying heat to the heat exchanger may be a combustion portion itself of a combustion apparatus for burning various types of fuels, such as a combustion portion of a combustion heating apparatus.

Specific examples and evaluated results according to the present invention are described below.

### EXAMPLE 1

The thermoelectric conversion module shown in FIG. 1 was produced according to the following procedure. First, a production example of the thermoelectric element is described.

(n-Type Thermoelectric Element)

Ti, Zr and Hf having a purity of 99.9%, Ni having a purity of 99.99%, Sn having a purity of 99.99% and Sb having a purity of 99.999% were prepared as raw materials. They were weighed and mixed so as to have a composition (Ti_{0.3}Zr_{0.35}Hf_{0.35}) NiSn_{0.994}Sb_{0.006}. The material mixture was charged in a copper hearth which was water cooled in an arc furnace, and the furnace interior was evacuated to 2×10⁻³ Pa. Then, Ar having a purity of 99.999% was introduced to have −0.04 MPa. In the decompressed Ar atmosphere, the material mixture was arc-melted.

The obtained metal lump was pulverized and molded under a pressure of 50 MPa by a mold having an inner diameter of 20 mm. The molded body was loaded in a carbon mold having an inner diameter of 20 mm, and subjected to a press sintering treatment in the Ar atmosphere of 80 MPa under conditions of 1200° C. and one hour to obtain a disk-like sintered body having a diameter of 20 mm. A rectangular parallelepiped element having a side length of 2.7 mm and a height of 3.3 mm was cut out from the obtained sintered body as an n-type thermoelectric element. The thermoelectric element had a resistivity of 1.20×10⁻² Ωmm at 700K, a Seebeck coefficient of −280 nV/K, and a coefficient of thermal conductivity of 3.3 W/m·K.

(p-Type Thermoelectric Element)

Ti, Zr and Hf having a purity of 99.9%, Co having a purity of 99.9%, Sb having a purity of 99.999%, and Sn having a purity of 99.99% were prepared as raw materials. They were weighed and mixed so as to have a composition (Ti_{0.3}Zr_{0.35}Hf_{0.35}) CoSb_{0.85}Sn_{0.15}. The material mixture was charged in a copper hearth which was water cooled in an arc furnace, and the furnace interior was evacuated to 2×10⁻³ Pa. Then, Ar having a purity of 99.999% was introduced to have −0.04 MPa. In the decompressed Ar atmosphere, the material mixture was arc-melted.

The obtained metal lump was pulverized and molded under a pressure of 50 MPa by a mold having an inner diameter of 20 mm. The molded body was loaded in a carbon mold having an inner diameter of 20 mm, and subjected to a press sintering treatment in the Ar atmosphere of 70 MPa under conditions of 1300° C. and one hour to obtain a disk-like sintered body having a diameter of 20 mm. A rectangular parallelepiped element having a side length of 2.7 mm and a height of 3.3 mm was cut out from the obtained sintered body as a p-type thermoelectric element. The thermoelectric element had a resistivity of 2.90×10⁻² Ωmm at 700K, a Seebeck coefficient of 309 V/K, and a coefficient of thermal conductivity of 2.7 W/m·K.

The above-described p-type thermoelectric element and n-type thermoelectric element were used to produce a thermoelectric conversion module as follows.

(Thermoelectric Conversion Module)

In this Example, a silicon nitride ceramics plate (a coefficient of thermal conductivity=80 W/m·K, a three-point bending strength=800 MPa) was used as the first and second substrates, and a Cu plate was used as an electrode member to produce a thermoelectric conversion module. First, a bonding material having active metal brazing material in a paste state at a mass ratio of Ag:Cu:Sn:Ti:C=61:24:10:4:1 was screen printed on a silicon nitride plate having a side length of 40 mm and a thickness of 0.7 mm. It was dried, and a Cu electrode plate which was 2.8 mm long, 6.1 mm wide, 0.25 mm thick was disposed lengthwise in six and breadthwise in 12 on a bonding material. Thus, a total of 72 Cu electrode plates were disposed on the silicon nitride plate. Then, they were bonded by performing a heat treatment in vacuum of 0.01 Pa or less at 800° C. for 20 minutes. The above-described bonding material was used to bond a Cu plate on the entire surface of the other side of the silicon nitride plate on which the Cu electrode plates were disposed.

Then, the bonding material was screen printed on the Cu electrode plate, and it was dried to obtain a module substrate. Two module substrates were used and superposed with a thermoelectric element sandwiched between them. The thermoelectric element had p-type and n-type thermoelectric elements alternately disposed on the bonding material printed on the Cu electrode plate and arranged in a square shape with 6 sets vertically and 12 columns horizontally to have a total of 72 sets. To arrange the thermoelectric elements, rod-shape silicon nitride plates having a thickness of 0.45 mm were disposed as fixing jigs (spacers) in a grid pattern. As shown in FIG. 4 and FIG. 5, the fixing jigs 19, 20 were positioned by means of the supporting base 21 in which the slits 22 were formed at intervals of 0.5 mm. The individual thermoelectric elements and the Cu electrode plate were bonded by performing a heat treatment of the laminated body in vacuum of 0.01 Pa or less at 800° C. for 20 minutes. The area ratio of the thermoelectric element occupying the module was 73.8%.

The produced thermoelectric conversion module was measured for thermoelectric characteristics under the matched load conditions that a load having the same resistance value as the internal resistance was connected to the module with the high-temperature side set to 500° C., and the low-temperature side set to 55° C. The resistance of the module was measured from the I-V characteristics of the thermoelectric conversion module to determine the resistance value on the bonded interface. The average electromotive force per thermoelectric element was 188 μV/K. The internal resistance value was 1.67Ω, the voltage at the maximum output was 6.03V, the maximum output was 21.8 W, and the output density was 1.38 W/cm².

In addition, the thermoelectric conversion module of Example 1 was similarly measured with the high-temperature side set to 550° C. and the low-temperature side set to 59° C. The average electromotive force per thermoelectric element was 190 μV/K, the internal resistance value was 1.69Ω, the voltage at the maximum output was 6.70V, the maximum output was 26.6 W, and the output density was 1.68 W/cm². Thus, the thermoelectric conversion module had its output improved by increasing the use temperature. Since the bonded temperature is 800° C., less than 800° C. becomes an indication of the use temperature of the thermoelectric conversion module of Example 1.

### EXAMPLES 2 TO 7, COMPARATIVE EXAMPLES 1 TO 3

Same thermoelectric conversion modules as in Example 1 were produced in the same manner excepting that the areas and quantity of the thermoelectric element and the electrode member were changed. The thermoelectric conversion modules were evaluated for performance in the same manner as in Example 1. Table 1 and Table 2 show the structures of the individual thermoelectric conversion modules and the evaluated results.

TABLE 1

| | Ratio of | | | Number | Electromotive |
|---|---|---|---|---|---|
| | element | | Side of | of | force per |
| | occupied | Interelement | element | elements | element |
| | area (%) | spacing (mm) | (mm) | (Q'ty) | (μV/k) |
| E1 | 73.8 | 0.5 | 2.8 | 144 | 188 |
| | 73.8 | 0.5 | 2.8 | 144 | 190 |
| E2 | 69.4 | 0.5 | 2.3 | 196 | 184 |
| E3 | 86.2 | 0.4 | 4.6 | 64 | 189 |
| E4 | 78.2 | 0.4 | 2.8 | 144 | 189 |
| E5 | 69.0 | 0.6 | 2.7 | 144 | 183 |
| E6 | 69.1 | 0.7 | 3.1 | 100 | 183 |
| E7 | 83.9 | 0.3 | 3.0 | 144 | 189 |
| CE1 | 59.4 | 0.8 | 2.5 | 144 | 176 |
| CE2 | 54.6 | 1.1 | 2.8 | 100 | 175 |
| CE3 | 43.3 | 1.0 | 1.8 | 196 | 175 |

E = Example; CE = Comparative Example

TABLE 2

| | High-temp. | Low-temp. | Internal | | | |
|---|---|---|---|---|---|---|
| | side | side | resis- | Volt- | Max. | Output |
| | substrate | substrate | tance | age | output | density |
| | temp. (° C.) | temp. (° C.) | (Ω) | (V) | (W) | (W/cm²) |
| E1 | 500 | 55 | 1.67 | 6.03 | 21.8 | 1.38 |
| | 550 | 59 | 1.69 | 6.70 | 26.6 | 1.68 |
| E2 | 502 | 50 | 3.24 | 8.15 | 20.5 | 1.30 |
| E3 | 500 | 53 | 0.28 | 2.71 | 26.2 | 1.66 |
| E4 | 500 | 51 | 1.58 | 5.90 | 21.6 | 1.50 |
| E5 | 500 | 53 | 1.72 | 5.93 | 20.4 | 1.34 |
| E6 | 500 | 52 | 0.91 | 4.10 | 18.5 | 1.33 |
| E7 | 500 | 59 | 1.41 | 5.99 | 25.4 | 1.65 |
| CE1 | 500 | 51 | 2.07 | 5.68 | 15.6 | 0.99 |
| CE2 | 500 | 53 | 1.18 | 3.88 | 12.8 | 0.82 |
| CE3 | 500 | 51 | 5.30 | 7.70 | 11.2 | 0.72 |

E = Example; CE = Comparative Example

In Comparative Example 1, a thermoelectric element having a side length of 2.5 mm and a height of 3.3 mm was used to produce a thermoelectric conversion module having an interelement spacing of 0.8 mm. The element occupied area ratio was 59.4%. The module of Comparative Example 1 had large radiant heat from the element of the high-temperature side substrate in comparison with the module of Example 1, so that a temperature difference which was substantially applied to both ends of the thermoelectric element became small, and the voltage of the module became low. The average electromotive force per thermoelectric element was 176 μV/K. The thermoelectric characteristics were measured under the matched load conditions in the same manner as in Example 1 to find that the internal resistance value was 2.71Ω, the voltage at the maximum output was 5.68V, the maximum output was 15.6 W, and the output density was 0.99 W/cm².

Comparative Example 2 was performed using a thermoelectric element having the same size as in Example 1 with the element occupied area ratio set to less than 69%. Comparative Example 3 was performed using lots of small thermoelectric elements with the element occupied area ratio set to less than 69%. In comparison with Comparative Examples 1 to 3, it is seen that the thermoelectric conversion modules of Examples 1 to 7 have the element occupied area ratio of 69% or more, and an output density has been improved substantially.

In addition, a thermoelectric conversion module was produced using a brazing material not containing carbon and titanium as Comparative Example 4. In other words, a module having an interelement spacing of 0.4 mm was produced in the same manner as in Example 1 except that a bonding material having an Ag—Cu brazing material in a paste state at a mass ratio of Ag:Cu:Sn=60:30:10 was screen printed on a Cu electrode plate. But, the brazing material did not uniformly get wet or spread in this case, and there was a short circuit between the elements at a portion where wetting and spreading were excessive. Thus, it is seen that when the interelement spacing is narrowed to 0.7 mm or less, an active metal brazing material containing carbon is effective for bonding of the thermoelectric element and the electrode member.

### EXAMPLE 8

Here, the heat exchanger shown in FIG. 8 was produced by the following procedure. First, the thermoelectric conversion modules of Example 1 were arranged between a heat resistant steel flat plate and a corrosion resistant steel flat plate and fixed by them to produce a stacked plate. Output terminals from the individual modules were connected in series. Thus, the heat exchanger with the thermoelectric conversion modules was obtained with the heat resistant steel side of the stacked plate determined as a high temperature portion and the corrosion resistant steel side determined as a cooling portion. High temperature exhaust gas and cooling water were flown to the heat exchanger with the thermoelectric conversion module. For example, the waste incineration system shown in FIG. 9 is provided with the heat exchanger with the thermoelectric conversion module, thereby enabling to provide a boiler that steam and hot water can be obtained, and power generation can be performed.

The above-described heat exchanger with the thermoelectric conversion module is arranged on the surface of the boiler interior water pipe or the fins of the water pipe of the steam thermal power generating plant, the heat resistant steel flat plate side is determined on the side of the boiler interior, and the corrosion resistant steel flat plate side is determined on the side of the water pipe. Thus, electric power and steam supplied to the steam turbine can be obtained at the same time, and the steam thermal power generating plant with the efficiency improved can be obtained. In other words, when it is assumed that the power generation efficiency of the steam thermal power generating plant to generate electric power by the steam turbine only is ηA and the thermoelectric conversion efficiency of the heat exchanger is ηT, they are expressed as ηA=ηT+(1−ηT)ηP, and when a heat exchanger having thermoelectric conversion efficiency ηT is mounted on a steam thermal power generating plant having power generation efficiency ηP, the power generation efficiency can be improved by (1-ηTP)ηT only.

In addition, a thermoelectric power generating system was configured by fitting the heat exchanger with the thermoelectric conversion module to a midpoint of an exhaust pipe (exhaust gas passage) of an automobile engine. This thermoelectric power generating system takes out DC power from heat energy of the exhaust gas by the thermoelectric conversion module and regenerates in a storage battery mounted in the automobile. Thus, drive energy of the AC generator (alternator) provided in the automobile is reduced, and the fuel consumption rate of the automobile can be improved.

The heat exchanger may be air cooled. By applying an air-cooled heat exchanger to a combustion heating apparatus, the combustion heating apparatus that external supply of electric energy is not required can be realized. In a combustion heating apparatus comprising a combustion portion which burns a fuel such as a petroleum liquid fuel, a gas fuel or the like, a housing portion which houses the combustion portion and has an opening for emitting air including heat generated by the combustion portion to the front of the apparatus, and an air blowing portion which sends the air including the heat generated by the combustion portion to the front of the apparatus, the air-cooled heat exchanger is mounted on an upper part of the combustion portion. By this combustion heating apparatus, DC power can be obtained from a part of the heat of the combustion gas by the thermoelectric conversion module to drive the air blowing fan at the air blowing portion.

### INDUSTRIAL APPLICABILITY

The thermoelectric conversion module of the present invention enhances the occupied area ratio of the thermoelectric element, so that heat conducted from the high-temperature side substrate to the low-temperature side substrate by radiation can be decreased. Thus, the temperature difference between the top and bottom ends of the thermoelectric element becomes large, so that the element electromotive force can be improved. This thermoelectric conversion module exerts a good thermoelectric conversion function under a high temperature of 300° C. or more, so that it is effectively used for a heat exchanger and a thermoelectric power generator.

What is claimed is:

1. A thermoelectric conversion module, comprising:
a first substrate, disposed on a low-temperature side, having an element mounting region;
a second substrate, disposed on a high-temperature side, having an element mounting region;
first electrode members provided to the element mounting region of the first substrate;
second electrode members provided to the element mounting region of the second substrate so as to oppose the first electrode members; and
a plurality of thermoelectric elements disposed between the first electrode members and the second electrode members, the thermoelectric elements electrically connecting to both of the first and second electrode members,
wherein the thermoelectric conversion module is used at a temperature of 300° C. or more,
wherein an occupied area ratio of the thermoelectric elements in the element mounting region is 69% or more, where an area of the element mounting region of the substrate is area A, a total cross-sectional area of the thermoelectric elements is area B, and the occupied area ratio of the thermoelectric elements is (area B/area A)×100(%).

2. The thermoelectric conversion module according to claim 1,
wherein the occupied area ratio of the thermoelectric elements is 73% or more and 90% or less.

3. The thermoelectric conversion module according to claim 1,
wherein the adjacent thermoelectric elements have a space of 0.3 mm or more and 0.7 mm or less between them.

4. The thermoelectric conversion module according to claim 1,
wherein each of the thermoelectric elements has a cross-sectional area of 1.9 mm² or more and 100 mm² or less.

5. The thermoelectric conversion module according to claim 1,
wherein the area of the element mounting region of the substrate is 100 mm² or more and 10000 mm² or less.

6. The thermoelectric conversion module according to claim 1,
wherein the thermoelectric elements are 16 or more.

7. The thermoelectric conversion module according to claim 1,
wherein the thermoelectric elements are bonded to the first and second electrode members via an active metal brazing material layer containing carbon.

8. The thermoelectric conversion module according to claim 7,
wherein the active metal brazing material contains the carbon in a range of 0.5 mass % or more and 3 mass % or less.

9. The thermoelectric conversion module according to claim 7,
wherein the active metal brazing material contains an Ag—Cu alloy as a main material, at least one of active metal selected from Ti, Zr and Hf in a range of 1 mass % or more and 8 mass % or less, and the carbon in a range of 0.5 mass % or more and 3 mass % or less.

10. The thermoelectric conversion module according to claim 1, further comprising:
an insulating member disposed as a fixing jig between the plurality of thermoelectric elements.

11. The thermoelectric conversion module according to claim 10,
wherein the insulating member is arranged in a grid pattern between the plurality of thermoelectric elements.

12. The thermoelectric conversion module according to claim 1,
wherein the thermoelectric elements are composed of a thermoelectric material which has an intermetallic compound having an MgAgAs crystal structure as a main phase.

13. The thermoelectric conversion module according to claim 12,
wherein the thermoelectric material has a composition represented by a general formula:
AₓB_{y}X_{100-x-y}
(where, A represents at least one of element selected from Ti, Zr, Hf and rare-earth elements, B represents at least one of element selected from Ni, Co and Fe, X represents at least one of element selected from Sn and Sb, and x and y represent a numeral satisfying 30≦x≦35 atom % and 30≦y≦35 atom %).

14. The thermoelectric conversion module according to claim 1,
wherein an output of the thermoelectric conversion module to the area of the element mounting region of the substrate is 1.3 W/cm² or more.

15. The thermoelectric conversion module according to claim 1,
wherein the first and second substrates are composed of a ceramics member having at least one selected from silicon nitride, aluminum nitride, alumina, magnesia and silicon carbide as a main component.

16. The thermoelectric conversion module according to claim 1,
wherein the first and second electrode members are composed of a metal material having at least one selected from Cu, Ag and Fe as a main component.

17. The thermoelectric conversion module according to claim 1,
wherein the plurality of thermoelectric elements are provided with alternately disposed p-type thermoelectric elements and n-type thermoelectric elements, and the p-type thermoelectric elements and the n-type thermoelectric elements are connected in series by the first and second electrode members.

18. A heat exchanger, comprising:
a heating side;
a cooling side; and
the thermoelectric conversion module according to claim 1 disposed between the heating side and the cooling side.

19. A thermoelectric power generator, comprising:
the heat exchanger according to claim 18; and
a heat supply unit for supplying heat to the heat exchanger,
wherein the heat supplied by the heat supply unit is converted to electric power by the thermoelectric conversion module of the heat exchanger to generate electricity.

20. The thermoelectric power generator according to claim 19,
wherein the heat supply unit has an exhaust gas line of an incinerator, a boiler interior water pipe, an exhaust pipe of an internal combustion engine, or a combustion portion of a combustion apparatus.
